(19) United States
(12) Patent Application Publication
(10) Pub. No.: US 2025/0314701 A1
(43) Pub. Date: Oct. 9, 2025

(54) METHOD AND APPARATUS FOR THE CELL IMPEDANCE DETERMINATION OF A BATTERY CELL USING A FRACTIONAL MODEL AS WELL AS METHOD FOR PROVIDING A FRACTIONAL BATTERY MODEL

(71) Applicant: Robert Bosch GmbH, Stuttgart (DE)

(72) Inventors: Christian Loew, Stuttgart (DE); Ingo Priemer, Stuttgart (DE)

(21) Appl. No.: 19/098,455

(22) Filed: Apr. 2, 2025

(30) Foreign Application Priority Data
Apr. 4, 2024 (DE) 10 2024 203 103.8

(51) Int. Cl. G01R 31/367; G01R 31/387; G01R 31/389; G01R 31/392

(52) U.S. Cl. CPC G01R 31/367; G01R 31/387; G01R 31/389; G01R 31/392

(57) ABSTRACT

A method for providing a cell impedance model for a battery cell based on an equivalent circuit model with components having temperature-dependent component values and configured to model a terminal voltage and/or a cell impedance by providing a measurement time series of measured values in time steps, where the measured values each comprise a measured terminal voltage, a measured cell current, a measured cell external temperature, or a measured ambient temperature, and performing an optimization method for the model parameters of the cell impedance model. In each iteration, on a provisionally parameterized cell impedance model, a progression of the cell internal temperature is determined for the time steps, and the model parameters of the cell impedance model are optimized for the time steps by minimizing an entirety of the voltage differences between the measured terminal voltage and a terminal voltage modeled with the cell impedance model.

### BACKGROUND

The invention relates to battery cells and modeling cell impedances using a fractional battery model. The invention further relates to the consideration of a cell temperature for determining cell impedance.

The behavior of a battery may be modeled using a suitable battery model. In practice, equivalent circuit models, in particular in the form of a fractional model, have proven themselves in this respect to simulate the electrical behavior, in particular the impedance of the battery cell, based on a combination of resistances and capacitances. Due to the non-linearity, the component values, i.e. the resistance values and the capacitance values, are not constant, but are mapped as variable via the state of health of the battery cell, the state of charge, the current and the cell temperature in the fractional model.

In particular, such battery models are used to simulate batteries to determine whether predetermined current or load profiles can be met. Furthermore, the battery model can be used to predict how long a current or power requested by the higher-level controller can be provided without violating any of the operating limits set by the battery cell manufacturer.

For the application of the cell impedance model, the state of health SOH-R of the battery cell related to an impedance change is determined using a separate state of health model.

The state of charge may be determined by time integration of all charge inlets and outlets. The cell temperature may be determined by a temperature sensor thermally well connected to the battery cell.

### SUMMARY

According to the invention, there is provided a method for using a cell impedance model for a battery cell as well as a method for providing a cell resistance model.

Further configurations are specified in the dependent claims.

According to a first aspect, a method for providing a cell impedance model for a battery cell based on an equivalent circuit diagram with components having at least temperature-dependent component values and configured to model a terminal voltage and/or a cell impedance with the following steps:
providing at least one measurement time series of measured values in time steps, wherein the measured values each comprise a measured terminal voltage, a measured cell current, a measured cell external temperature, or a measured ambient temperature,
performing an optimization method for the model parameters of the cell impedance model wherein in each iteration,
   on a provisionally parameterized cell impedance model, a progression of the internal cell temperature is determined for the time steps of the measurement time series based on a predetermined temperature model as a function of the respective measured cell external temperature or the measured ambient temperature and a power dissipation respectively, and
   furthermore, the model parameters of the cell impedance model are optimized for all time steps by minimizing an entirety of the voltage differences between the measured terminal voltage and a terminal voltage modeled with the cell impedance model, wherein the modeled terminal voltages are determined in each case as a function of the cell internal temperature of the respective time step determined for the respective time step using the cell impedance model.

The temperature model may be created, for example, using mechanical variables and electrochemical properties of the materials used in the battery cell with a tool such as Ansys.

One problem with modeling a battery cell based on a cell temperature measured using a temperature sensor is that the measured temperature cannot be measured directly inside the battery cell. While a common temperature sensor is thermally well connected, it is spaced apart from the core of the battery cell. The specification of the cell temperature is therefore often inaccurate, has a low-pass behavior with regard to the actual temperature and in particular also depends on the ambient temperature and the current installation situation of the battery cell.

A cell impedance model, often referred to as an equivalent circuit model (ECM), is used to model a cell impedance of a battery cell based on an equivalent circuit that can be used to simulate a current-voltage characteristic of the battery cell. It typically consists of a combination of resistors, capacitors, and a voltage source that specifies an open circuit voltage corresponding to a known open circuit voltage (OCV) characteristic. Serial resistors represent the instant voltage drop in the battery under load and are caused by internal resistances of the battery cell. Furthermore, one or more polarization resistors and one or more capacitors may be included as RC elements with one or more time constants that model the slower electrochemical processes in the battery, wherein the polarization resistor models the delay in the voltage change due to chemical reactions in the battery cell and the capacitance of the capacitor models the capability of the battery to store and release charge and specifies the time delay in the voltage response.

It may be provided that the model parameters of the cell impedance model further indicate a dependence of the component values on a state of charge and/or state of health and/or a cell current.

The resistance values and capacitance values of the components of the cell impedance model represent model parameters of the battery model and may typically be dependent on the state of aging and/or state of charge and/or cell current in addition to the cell temperature.

The parameters of the cell impedance model are determined based on measurement time series using a known parameterization method, such that the behavior modeled with the equivalent circuit model corresponds to the real behavior of the battery cell. The parameterization method comprises an iterative optimization method in which the parameter values are determined incrementally. The measurement time series include time series of current-voltage measurements and/or frequency series of impedances and phase shifts, e.g., determined via electrochemical impedance spectroscopy (EIS).

It is therefore provided to extend the cell impedance model by specifying the dependence of the model parameters, i.e. the resistance values and the capacitance values, on the temperature, using a cell internal temperature determined using a temperature model. The resulting temperature specification for the cell internal temperature is used instead of the cell external temperature measured using the temperature sensor.

The temperature model provides for using the power dissipation in the battery cell based on the current operating point from voltage and/or current and cell resistance in the battery cell, the measured temperature outside the battery cell, possibly an ambient temperature and the like in a temperature model, in order to model a temperature specification for a cell internal temperature as is present inside the battery cell.

The temperature model takes into account a heat power balance and may be modeled as a first-order differential equation model or by more complex models or data-based models.

This temperature model is taken into account for parameterizing the cell impedance model in each iteration so that the model parameters of the resistance values and capacitance values are always optimized in relation to a cell internal temperature of the temperature model.

Furthermore, the parameterization may be carried out using a minimization of the voltage differences between the measured terminal voltage and the terminal voltage of the measured time series under consideration modeled with the cell impedance model.

Thus, when parameterizing the cell impedance model and the temperature model, an iterative optimization method can be performed based on time series of measured variables, wherein a progression of the cell internal temperature modeled for each iteration is used instead of a measured temperature specification. The respective cell internal temperature (for each time step) for consideration using the cell impedance model results from the power dissipation in the equivalent circuit diagram for a time step t.

$$P ( t ) = {i ( t )}^{2} {R}_{0} + \frac{{{u}_{I} ( t )}^{2}}{{R}_{I}} + \frac{{{u}_{2} ( t )}^{2}}{{R}_{2}} + …$$

Using the cell current i(t), the series resistanceR₀, the voltages (terminal voltages) u₁(t), u₂(t), . . . over each of the RC elements R₁, C₁, R₂, C₂, . . . the temperature model is predetermined. Alternatively, the temperature model may be parameterized with in the parameterization of the cell impedance model.

According to a further aspect, a method for determining a cell impedance of a battery cell using a cell impedance model at a time step is provided, with the steps of:
determining a cell internal temperature of the battery cell as a function of a measured cell external temperature or a measured ambient temperature and as a function of an electrical power dissipation converted in the battery cell in a preceding the time step using a predetermined temperature model;
determining the component parameters as a function of the cell internal temperature;
determining the cell impedance as a function of the cell impedance of the preceding time step using the cell impedance model configured with the determined component parameters.

In the evaluation of the cell impedance model, a cell temperature specification is thus first determined using the parameterized temperature model. To this end, in each time step, an electrical power converted in the battery cell is determined, a temperature outside of the battery cell is detected, e.g., using the temperature sensor, and possibly an ambient temperature is detected. A temperature specification may then be determined for the current time step by the temperature model based on time series integration.

Furthermore, the cell impedance model is evaluated, wherein the model parameters are determined and used as a function of the modeled temperature specification so that the cell impedance can be determined.

### BRIEF DESCRIPTION OF THE DRAWINGS

Embodiments are explained in more detail below with reference to the accompanying drawings. Shown are:

FIG. 1 is a schematic illustration of an equivalent circuit diagram of a cell impedance model; and

FIG. 2 is a functional block diagram illustrating the function of the extended cell impedance model;

FIG. 3 a flowchart illustrating a method for parameterizing the cell impedance model.

### DETAILED DESCRIPTION

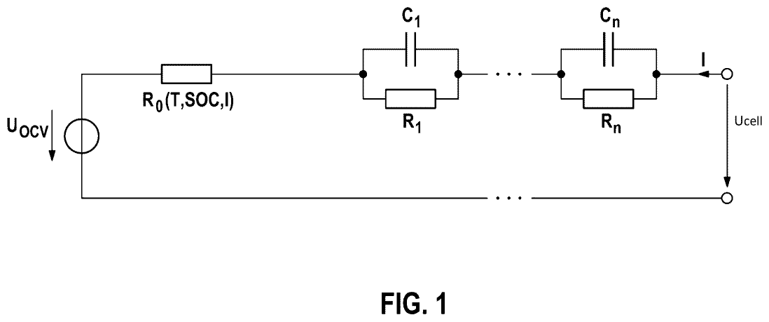

FIG. 1 schematically shows a cell impedance model corresponding to an equivalent circuit diagram to map the electrical behavior of a battery cell.

The equivalent circuit diagram is constructed with electrical components each comprising one or more parameterizable electrical variable(s). The parameterizable electrical variable may further be dependent on parameters such as cell temperature, state of charge and cell current. The equivalent circuit diagram comprises a serial resistor R₀ electrically connected in series with a plurality of (n) serially connected RC elements (R parallel to C) having a first resistance R₁ and a first capacitance C₁ or an nth resistance Rₙ and an nth capacitance Cₙ, respectively.

The resistance values and capacitance values of the individual components of the equivalent schematic model are dependent on the cell temperature T and may also be modeled as a function of a state of health SOH of the battery cell and a state of charge SOC of the battery cell and a cell current I.

R₀=f(SOH,SOC,T,I)

R_{1 . . . n}=g(SOH,SOC,T,I)

C_{1 . . . n}=h(SOH,SOC,T,I)

To parameterize the cell impedance model with its parameters, one or more measurement time series are now recorded at successive sampling points in time steps t=1 . . . k, in which the respective terminal voltage, the current state of charge, the associated battery current and the current cell temperature are taken into account. The state of charge may be determined, for example, by time integration of the charge inlets and outlets.

The state of health may be determined using a known state of health model to determine a state of health SOH-R affecting the cell impedance change, and may be assumed to be constant for the duration of the measurement of time series.

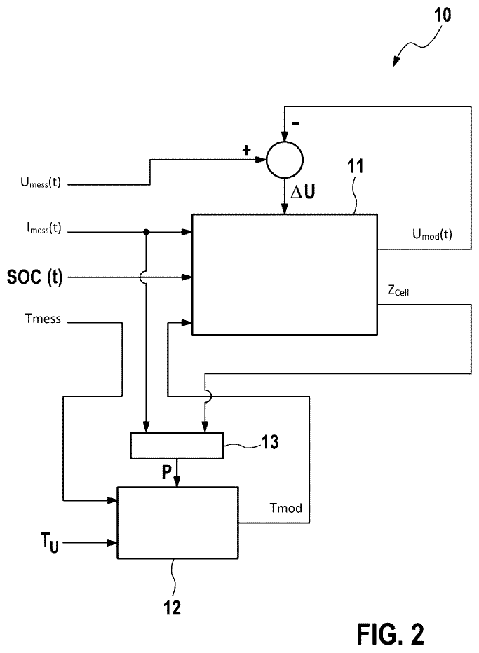

FIG. 2 shows a block diagram of a model set-up 10 for providing the cell impedance model 11 in conjunction with a temperature model 12.

When a battery current Iₘₑₛₛ(t), is applied, at a particular state of charge SOC and a particular cell temperature T, a cell voltage Uₘₑₛₛ can then be measured and compared to the terminal voltages U_{mod}(t) modeled using the cell impedance model 11.

The parameterization of the cell impedance model 11 is usually carried out based on measurement time series of measurement datasets, in particular to be able to accurately map the time behavior resulting from the capacitances of the capacitors and from the temperature inertia of the cell internal temperature. The measurement is carried out by detecting time series of the battery current Iₘₑₛₛ(t), the cell external temperature Tₘₑₛₛ(t) or the ambient temperature and the cell voltage Uₘₑₛₛ(t).

$${u}_{m o d} ( t ) = i ( t ) * {Z}_{z e l l e}$$

with the cell impedance Z_{cell}.

By minimizing the voltage differences between the measured and modeled terminal voltage Uₘₑₛₛ(t), U_{mod}(t) in the entirety of all time steps of the time series, parameterization of the model parameters of the cell impedance model 11 can be carried out. However, this approach conventionally leads to high voltage differences between the measured and modeled clamping voltage Uₘₑₛₛ(t), U_{mod}(t) due to the inaccurate information available on the internal cell temperature, so that it is proposed herein to extend the cell impedance model 11 with a temperature model 12 that provides a more accurate specification of the cell internal temperature.

The temperature model 12 can provide for determining a cell internal temperature T_{mod}(t) as a current temperature specification as a function of time series of a measured cell outer temperature Tₘₑₛₛ(t), which is typically measured outside the battery cell using a temperature sensor, and as a function of a time series of the power dissipation P(t) converted reacted in the battery cell.

In order to take into account historical power dissipations in particular, the temperature model 12 is configured in the form of a differential equation or a data-based recurrent model, which makes it possible to determine the cell internal temperature T_{mod}(t) as a temperature specification from the time series of the power dissipations and the time series of the cell external temperatures. Additionally or alternatively, an ambient temperature Tᵤ(t) of the battery cell may be considered. If the ambient temperature, Tᵤ(t) is used, it is also possible to dispense with detecting the cell external temperature.

For example, the temperature model may have the following form of a differential equation.

$$dx ( t ) / dt = A * x ( t ) + B * u ( t )$$

$${T}_{m o d} ( t ) = C * x ( t )$$

$$with u ( t ) = {( {T}_{u} ( t ) ; P ( t ) )}^{T}$$

$$P ( t ) = {i ( t )}^{2} {R}_{0} + \frac{{{u}_{1} ( t )}^{2}}{{R}_{1}} + \frac{{{u}_{2} ( t )}^{2}}{{R}_{2}} + …$$

with parameters A, B, C of the temperature model.

In contrast to the conventional method of using an optimization method for minimizing the voltage differences between the time series of the measured terminal voltage and the time series of the modeled terminal voltage, the temperature specifications for each time step of the measurement time series are now first determined in an iteration step of the optimization method as a function of the current parameter values of the model parameters and then the parameters of the model parameters of the cell impedance model 11 are adjusted based on voltage difference, assuming a previously determined current cell temperature specification T_{mod}(t). The adjusted model parameters may be evaluated with the cell impedance model, resulting in cell impedance Z_{cell}. The resulting cell impedance Z_{cell} is recursively used to Z_{cell} calculate a power dissipation P in a power dissipation block 13 based on based on the battery current Iₘₑₛₛ(t) and the modeled cell impedance and to use the power dissipation P(t) and the cell external temperature Tₘₑₛₛ(t) in the temperature model 12.

In the next iteration step, this power dissipation P(t) is used to recalculate the progression of the cell internal temperature T_{mod}(t) as a temperature specification for the time steps. The resulting progression of the cell internal temperature T_{mod}(t) is now reapplied in the cell impedance model 11 to obtain an updated cell impedance Z_{cell}.

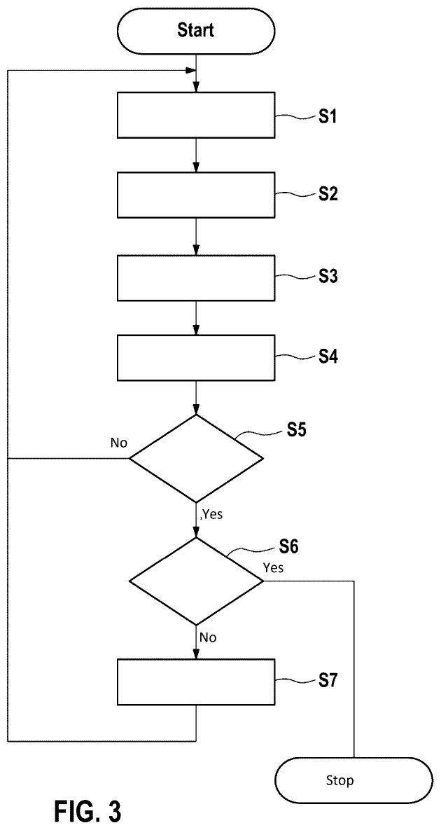

In FIG. 3, a flow chart for illustrating the procedure of the parameterization method is shown.

In step S1, a measurement time series is provided, wherein the battery cell is relaxed at the beginning of the measurement time series, i.e. the terminal voltage corresponds to the OCV voltage and the cell internal temperature T_{mod}(t) as a temperature specification corresponds to the ambient temperature. Furthermore, an initial parameterized temperature model is provided.

In step S2, the cell impedance is calculated in the time step t of the measurement time series with the temperature specification of the time step t−1 using the cell impedance model initially parameterized or parameterized in the course of this optimization method. As the time series is based on the time step t=1 at which the cell internal temperature corresponds to the ambient temperature or is otherwise known.

In step S3, the resulting modeled terminal voltage U_{mod}(t) and the resulting power dissipation P(t) are calculated in the time step t.

In step S4, the cell temperature is calculated as a temperature specification in time step t as a function of the power dissipation using the temperature model.

In step S5, it is checked whether a temperature specification has been determined for all the sampling points of the measurement time series. If this is the case (alternative: yes), the method continues with step S6. Otherwise (alternative: no) the method returns to step S2 until temperature specifications have been calculated for all time steps t of the measurement time series. Thus, at each time step t/sampling point of the measurement time series, a temperature specification of the cell internal temperature is obtained.

Step S6 checks whether the sum or the average value of the squared voltage differences of the terminal voltages U_{mod}(t) modeled in step S3 and the measured terminal voltages Uₘₑₛₛ(t) fall below a predetermined limit value for all time steps. If so (alternative: yes), the optimization process has converged and the process is terminated. Otherwise (alternative: no), the method continues with step S7.

In step S7, the model parameters of the cell impedance model are recalculated using the sum or the mean of the squared voltage differences calculated in step S6, and, if applicable, all results of the previous iterations, e.g., using the least square method.

The method then continues in step S2 with the next iteration.

The optimization may be based on a gradient descent method, wherein the entirety (e.g. in the form of a sum, a sum of the squares) of the voltage differences between the measured terminal voltage Uₘₑₛₛ(t) and the modeled terminal voltage U_{mod}(t) at each time step/sampling point may be used by parameter adjustment of the model parameters of the cell impedance model 11 over the time series of the measurement data set under consideration.

1. A computer-implemented method for providing a cell impedance model (11) for a battery cell based on an equivalent circuit model (11) with components having at least temperature-dependent component values and configured to model a terminal voltage and/or a cell impedance (Z_{cell}), the method comprising:
providing (S1), to a computer. at least one measurement time series of measured values in time steps, wherein the measured values each comprise a measured terminal voltage (Uₘₑₛₛ(t)), a measured cell current (Iₘₑₛₛ(t)), a measured cell external temperature (Tₘₑₛₛ(t)), or a measured ambient temperature, and
performing, via the computer, an optimization method for the model parameters of the cell impedance model wherein in each iteration,
on a provisionally parameterized cell impedance model (11), a curve of the internal cell temperature (T_{mod}(t)) is determined for the time steps (t) of the measurement time series based on a predetermined temperature model (12) as a function of the respective measured cell external temperature (Tₘₑₛₛ(t)) or the measured ambient temperature and a power dissipation (P) respectively (S2-S4), and
the model parameters of the cell impedance model (11) are optimized (S7) for the time steps of the measurement time series by minimizing an entirety of the voltage differences between the measured terminal voltage (Uₘₑₛₛ(t)) and a terminal voltage (U_{mod}(t)) modeled with the cell impedance model, wherein the modeled terminal voltages (U_{mod}(t)) are determined in each case as a function of the cell internal temperature (T_{mod}(t)) of the respective time step (t) determined for the respective time step using the cell impedance model (11).

2. The method according to claim 1, wherein the model parameters of the cell impedance model (11) further specify a dependence of the component values on a state of charge (SOC) and/or a state of health (SOH) and/or a cell current.

3. The method according to claim 1, wherein the parameterization is carried out using a minimization of a deviation value from the voltage differences between the measured terminal voltage (Uₘₑₛₛ(t)) and the terminal voltage (U_{mod}(t)) modeled with the cell impedance model (11) of the at least one measurement time series under consideration for all time steps (t).

4. A method for determining a cell impedance (Z_{cell}) of a battery cell using a cell impedance model (11) at a time step, the method comprising:
determining, via a computer, a cell internal temperature of the battery cell as a function of a measured cell external temperature (Tₘₑₛₛ(t)) or a measured ambient temperature using a temperature model (12) and as a function of an electrical power dissipation (P(t)) converted in the battery cell in a time step (t−1) preceding the time step (t);
determining, via the computer, the component parameters as a function of the internal cell temperature (T_{mod}(t)); and
determining, via the computer, the cell impedance as a function of the cell impedance (Z_{cell}) of the preceding time step (t−1) using the cell impedance model (11) configured with the determined component parameters.

5. A non-transitory, computer-readable storage medium comprising instructions that, when executed by a computer, prompt the latter to:
determine a cell internal temperature of the battery cell as a function of a measured cell external temperature (Tₘₑₛₛ(t)) or a measured ambient temperature using a temperature model (12) and as a function of an electrical power dissipation (P(t)) converted in the battery cell in a time step (t−1) preceding the time step (t);
determine the component parameters as a function of the internal cell temperature (T_{mod}(t)); and
determine the cell impedance as a function of the cell impedance (Z_{cell}) of the preceding time step (t−1) using the cell impedance model (11) configured with the determined component parameters.
